(19) United States
(12) Patent Application Publication
(10) Pub. No.: US 2026/0141948 A1
(43) Pub. Date: May 21, 2026

(54) MEMORY DEVICE

(71) Applicant: Winbond Electronics Corp., Taichung City (TW)

(72) Inventor: Shu-Meng Yang, Hualien (TW)

(73) Assignee: Winbond Electronics Corp., Taichung City (TW)

(21) Appl. No.: 19/305,806

(22) Filed: Aug. 21, 2025

(30) Foreign Application Priority Data
Nov. 18, 2024 (TW) 113144238

(51) Int. Cl. G11C 11/4091

(52) U.S. Cl. CPC G11C 11/4091

(57) ABSTRACT

Provided is a memory device, including a first bit line, a first word line, a second bit line, a second word line, a sensing amplifier circuit, and a voltage supply circuit. The first bit line and the second bit line are respectively coupled to a first memory cell and a second memory cell. The second bit line is complementary to the first bit line. The sensing amplifier circuit includes a first transistor and a second transistor. The first transistor and the second transistor are coupled in series between the first bit line and the second bit line. The sensing amplifier circuit includes a first node located between the first bit line and the second bit line. The voltage supply circuit is coupled to the sensing amplifier circuit.

### CROSS-REFERENCE TO RELATED APPLICATION

This application claims the priority benefit of Taiwan application serial no. 113144238, filed on Nov. 18, 2024. The entirety of the above-mentioned patent application is hereby incorporated by reference herein and made a part of this specification.

### BACKGROUND

### Technical Field

The disclosure relates to an electronic component, and in particular to a memory device.

### Description of Related Art

A memory device (such as a dynamic random access memory) can store bit data in a memory cell array. The memory cell array is composed of multiple memory bits, which are correspondingly configured with multiple word lines and bit lines. The memory cell may be composed of a transistor and a capacitor coupled in series. Generally speaking, a bit data 1 and a bit data 0 are respectively implemented through storing a high-voltage potential and a low-voltage potential on the nodes of the capacitor.

However, as the dimension of semiconductor components and technology nodes gets smaller, the input offset voltage for sensing the bit data also increases. In order to overcome the increased input offset voltage for sensing the data, the high-voltage potential of storing data is difficult to be reduced. Therefore, the goal of implementing a low power consumption memory is difficult.

### SUMMARY

The disclosure provides a memory device, which can reduce a voltage potential of storing a bit data to implement a low power consumption design.

The memory device according to an embodiment of the disclosure includes a first bit line, a first word line, a second bit line and a second word line, a sensing amplifier circuit and a voltage supply circuit. The first bit line and the second bit line are respectively coupled to a first memory cell and a second memory cell. The second bit line is complementary to the first bit line. The sensing amplifier circuit includes a first transistor and a second transistor. The first transistor and the second transistor are coupled in series between the first bit line and the second bit line. The sensing amplifier circuit includes a first node located between the first bit line and the second bit line. A gate terminal of the first transistor is coupled to the second bit line, and a gate terminal of the second transistor is coupled to the first bit line. The voltage supply circuit is coupled to the sensing amplifier circuit. The voltage supply circuit is configured to provide a first voltage to the first node during a post-restoration period of storing a bit voltage data. The first voltage is a negative voltage. The post-restoration period of storing the bit voltage data is between a sensing and pre-restoration period of storing the bit voltage data and a pre-charge period of a bit line.

### BRIEF DESCRIPTION OF THE DRAWINGS

FIG. 1 is a circuit schematic diagram of a memory device according to an embodiment of the disclosure.

FIG. 2A is a timing schematic diagram of the memory device performing a sensing operation according to the embodiment of FIG. 1.

FIG. 2B is a corresponding control signal diagram of different periods according the embodiment of FIG. 2A.

FIG. 3A is a schematic diagram of a storage voltage of a memory device according to a related art.

FIG. 3B is a circuit schematic diagram of a memory device according to an embodiment of the disclosure.

### DESCRIPTION OF THE EMBODIMENTS

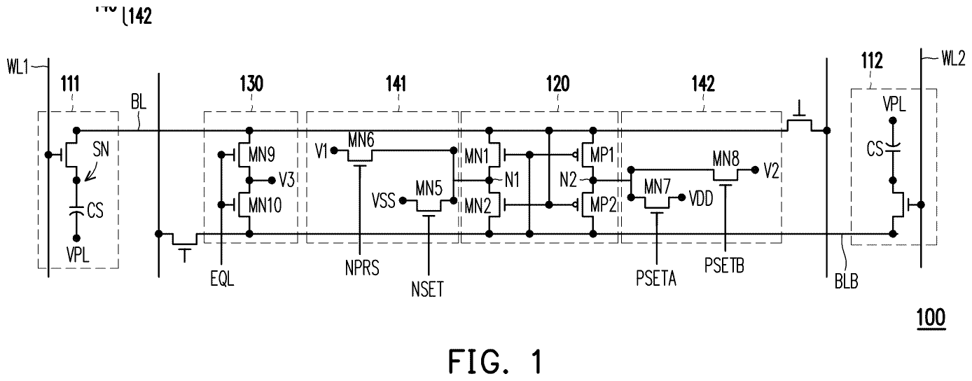

Refer to FIG. 1. In the embodiment, a memory device 100 includes a first bit line BL, a first word line WL1, a second bit line BLB, a second word line WL2, memory cells 111 and 112, a sensing amplifier circuit 120, an equalizer circuit 130, and a voltage supply circuit 140.

The memory cells 111 and 112 are configured to store data. The memory cell 111 is a selected memory cell, and the memory cell 112 is an unselected memory cell. The first bit line BL and the second bit line BLB are respectively coupled to the memory cells 111 and 112. The second bit line BLB is complementary to the first bit line BL. One end of a capacitor CS of the memory cell 111 or 112 is coupled to a plate voltage VPL. The plate voltage VPL is, for example, half of a bit line high voltage VBLH.

The equalizer circuit 130 includes a first equalizing transistor MN9 and a second equalizing transistor MN10. A control signal EQL is coupled to the gates of the first equalizing transistor MN9 and the second equalizing transistor MN10. The first equalizing transistor MN9 and the second equalizing transistor MN10 equalize the first bit line BL and the second bit line BLB based on the control signal EQL.

The sensing amplifier circuit 120 includes a first transistor MN1, a second transistor MN2, a third transistor MP1, and a fourth transistor MP2. The first transistor MN1 and the second transistor MN2 are NMOS transistors, and the third transistor MP1 and the fourth transistor MP2 are PMOS transistors.

The first transistor MN1 and the second transistor MN2 are coupled in series between the first bit line BL and the second bit line BLB. The sensing amplifier circuit 120 includes a first node N1 located between the first bit line BL and the second bit line BLB. A gate terminal of the first transistor MN1 is coupled to the second bit line BLB, and a gate terminal of the second transistor MN2 is coupled to the first bit line BL.

The third transistor MP1 and the fourth transistor MP2 are coupled in series between the first bit line BL and the second bit line BLB. The sensing amplifier circuit 120 includes a second node N2 located between the first bit line BL and the second bit line BLB. A gate terminal of the third transistor MP1 is coupled to the second bit line BLB, and a gate terminal of the fourth transistor MP2 is coupled to the first bit line BL.

The voltage supply circuit 140 includes a first voltage supply cell 141 and a second voltage supply cell 142. The first voltage supply cell 141 is coupled to the first node N1. The second voltage supply cell 142 is coupled to the second node N2.

The first voltage supply cell 141 includes a fifth transistor MN5 and a sixth transistor MN6. The fifth transistor MN5 provides a first power voltage VSS to the first node N1 based on a control signal NSET. In the embodiment, the first power voltage VSS is, for example, a ground voltage. The sixth transistor MN6 provides a first voltage V1 to the first node N1 based on a control signal NPRS. In the embodiment, the first voltage V1 is a negative voltage.

The second voltage supply cell 142 includes a seventh transistor MN7 and an eighth transistor MN8. The seventh transistor MN7 and the eighth transistor MN8 may be implemented using transistor components with thin oxide channel layer structures to reduce a chip area occupied by the transistor components. The seventh transistor MN7 provides a second power voltage VDD to the second node N2 based on a control signal PSETA. In the embodiment, the second power voltage VDD is, for example, a high power voltage supplied by the outside. The eighth transistor MN8 provides a second voltage V2 to the second node N2 based on a control signal PSETB. In the embodiment, the second voltage V2 is greater than the first voltage V1. For example, the second voltage V2 may be a reference voltage minus an absolute value of the first voltage V1, that is, V2=VBLH−|V1|. VBLH is the bit line high voltage, serving as an example of the reference voltage, and |V1| is the absolute value of the first voltage V1.

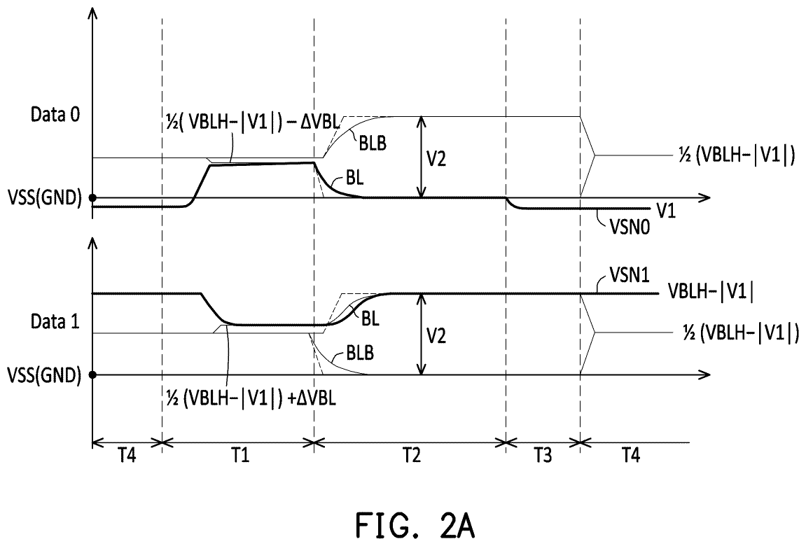

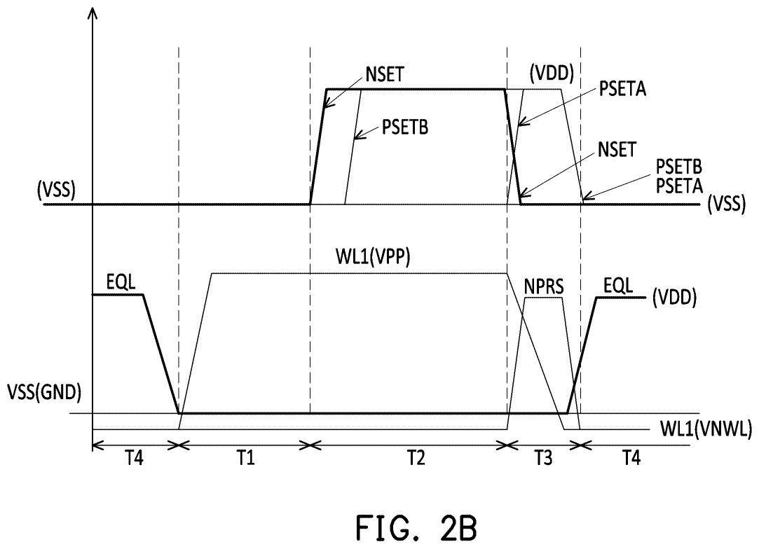

Refer to FIG. 1 to FIG. 2B. The timing of a sensing operation of the memory device 100 includes a pre-charge period T4, a charge sharing period T1, a sensing and pre-restoration period T2, and a post-restoration period T3. After the post-restoration period T3, the embodiment returns to the pre-charge period T4 again. A timing diagram in FIG. 2A illustrates the voltage changes between the first bit line BL and the second bit line BLB during each period, and voltage changes VSN0 and VSN1 of a node SN when the memory cell 111 stores a data “0” (a first bit value) and a data “1” (a second bit value).

During the pre-charge period T4, due to the action of the equalizer circuit 130, the first bit line BL and the second bit line BLB are pre-charged to a predetermined voltage V3 that is greater than the first power voltage VSS and less than the second power voltage VDD. In the embodiment, the predetermined voltage V3 is, for example, half of VBLH−|V1|, that is:

$$V 3 = \frac{1}{2} ( VBLH - \vert V 1 \vert )$$

During the charge sharing period T1, the word line WL coupled to the selected memory cell 111 is activated, and the first bit line BL shares charge with the capacitor CS of the selected memory cell 111. Therefore, when the data is “0” (the first bit value), the voltage of the first bit line BL is reduced by ΔVBL. When the data is “1” (the second bit value), the voltage of the first bit line BL is increased by ΔVBL. ΔVBL is a bit line charge sharing voltage difference.

During the sensing and pre-restoration period T2 of storing a bit voltage data, the control signals NSET and PSETB respectively turn on the fifth transistor MN5 and the eighth transistor MN8. Therefore, the voltage supply circuit 140 may provide the first power voltage VSS to the first node N1 of the sensing amplifier circuit 120 and provide the second voltage V2 to the second node N2. Therefore, the voltage difference between the first bit line BL and the second bit line BLB is amplified. That is, when the bit storage data is “0”, the voltage of the first bit line BL is reduced to the first power voltage VSS, and the voltage of the second bit line BLB is increased to the second voltage V2. When the bit storage data is “1”, the voltage of the first bit line BL is increased to the second voltage V2, and the voltage of the second bit line BLB is reduced to the first power voltage VSS. Therefore, the voltage difference between the first bit line BL and the second bit line BLB is V2, that is, VBLH−|V1|<VBLH, reducing the voltage of the bit storage data “1” and decreasing the sensing amplifying leakage current of the first bit line and the second bit at this time.

During the post-restoration period T3 of storing the bit voltage data, the control signals NPRS and PSETA respectively turn on the sixth transistor MN6 and the seventh transistor MN7. Therefore, the voltage supply circuit 140 may provide the first voltage V1 to the first node N1 of the sensing amplifier circuit 120. The first voltage V1 is a negative voltage. Moreover, the voltage supply circuit 140 provides the second power voltage VDD minus a threshold voltage of the seventh transistor MN7 to the second node N2. That is, when the bit storage data is “0”, the voltage of the first bit line BL may be further reduced from VSS to the first voltage V1. When the bit storage data is “1”, the voltage of the first bit line BL is the second voltage V2.

After the post-restoration period T3 of storing the bit voltage data, the embodiment returns to the pre-charge period T4 again. The equalizer circuit 130 pre-charges the first bit line BL and the second bit line BLB to the predetermined voltage V3, that is, half of VBLH−|V1|. In this way, the memory device 140 completes the sensing and restoration operation of storing the bit voltage data.

In the embodiment, the timing of the sensing operation is that the charge sharing period T1 or the sensing and pre-restoration period T2 of storing the bit voltage data may be triggered by an ACT command provided by a memory controller. The post-restoration period T3 of storing the bit voltage data or the pre-charge period T4 of the bit line may be triggered by a PRE command provided by the memory controller. In addition, in FIG. 2A, the second voltage V2 is greater than the predetermined voltage V3, the predetermined voltage V3 is greater than the first power voltage VSS, and the first power voltage VSS is greater than the first voltage V1. In FIG. 2B, VPP is a word line high voltage, VNWL is a word line low voltage, and GND is a ground voltage.

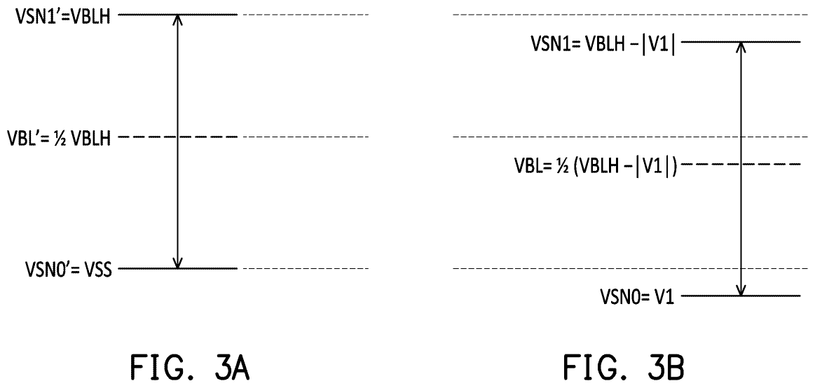

FIG. 3A is a schematic diagram of a storage voltage of a memory device according to a related art. FIG. 3B is a circuit schematic diagram of a memory device according to an embodiment of the disclosure. Refer to FIG. 3A and FIG. 3B. VBL and VBL′ are bit line voltages. In FIG. 3A, when a data is “1”, a storage voltage VSN1′ of the memory device is the bit line high voltage VBLH. When the data is “0”, a storage voltage VSN0′ of the memory device is the first power voltage VSS.

In FIG. 3B, according to the circuit structure of the memory device 100 in FIG. 1 and the timing of the sensing operation in FIG. 2A, when a data is “1”, the storage voltage VSN1 of the memory device 100 is the second voltage V2, that is, V2=VBLH−|V1|. When the data is “0”, the storage voltage VSN0 of the memory device 100 is the first voltage V1. VSN1 and VSN0 are respectively the voltages of the node SN when storing the bit values 1 and 0.

In summary, according to the embodiment of the disclosure, the voltage supply circuit provides the second voltage V2 to the second node of the sensing amplifier circuit, that is, V2=VBLH−|V1|<VBLH, during the sensing and pre-restoration period T2 of storing the bit voltage data, reducing the voltage of the bit storage data “1” and decreasing the sensing amplifying leakage current of the first bit line and the second bit line at this time. During the post-restoration period T3 of storing the bit voltage data, the negative voltage V1 is provided to the first node of the sensing amplifier circuit to store the bit data “0” in order to allow the voltage of the data storage operation of the memory to be reduced, implementing a low power consumption design of the memory.

Although the disclosure has been disclosed in the above embodiments, the embodiments are not intended to limit the disclosure. Persons skilled in the art may make some changes and modifications without departing from the spirit and scope of the disclosure. Therefore, the protection scope of the disclosure shall be defined by the appended claims.

What is claimed is:

1. A memory device, comprising:
a first bit line, a first word line, a second bit line and a second word line, respectively coupled to a first memory cell and a second memory cell, wherein the second bit line is complementary to the first bit line;
a sensing amplifier circuit, comprising a first transistor and a second transistor, coupled in series between the first bit line and the second bit line, wherein the sensing amplifier circuit comprises a first node located between the first bit line and the second bit line, a gate terminal of the first transistor is coupled to the second bit line, and a gate terminal of the second transistor is coupled to the first bit line; and
a voltage supply circuit, coupled to the sensing amplifier circuit, and configured to provide a first voltage to the first node during a post-restoration period of storing a bit voltage data, wherein the first voltage is a negative voltage, and the post-restoration period of storing the bit voltage data is between a sensing and pre-restoration period of storing the bit voltage data and a pre-charge period of a bit line.

2. The memory device according to claim 1, wherein the first memory cell stores a first bit value with the first voltage provided by the voltage supply circuit during the post-restoration period of storing the bit voltage data.

3. The memory device according to claim 2, wherein the sensing amplifier circuit further comprises a third transistor and a fourth transistor, coupled in series between the first bit line and the second bit line, wherein the sensing amplifier circuit comprises a second node located between the first bit line and the second bit line, a gate terminal of the third transistor is coupled to the second bit line, and a gate terminal of the fourth transistor is coupled to the first bit line.

4. The memory device according to claim 3, wherein the voltage supply circuit is further configured to provide a second voltage to the second node during the sensing and pre-restoration period of storing the bit voltage data, wherein the second voltage is an absolute value of a reference voltage minus the first voltage.

5. The memory device according to claim 4, wherein the first memory cell stores a second bit value with the second voltage.

6. The memory device according to claim 5, wherein the second voltage is greater than the first voltage.

7. The memory device according to claim 5, wherein the reference voltage is a bit line high voltage.

8. The memory device according to claim 4, further comprising:
an equalizer circuit, coupled between the first bit line and the second bit line, and configured to pre-charge the first bit line to a predetermined voltage during the pre-charge period of the bit line, where the predetermined voltage is half of the second voltage.

9. The memory device according to claim 8, wherein the voltage supply circuit provides a first power voltage to the first node of the sensing amplifier circuit and provides the second voltage to the second node during the sensing and pre-restoration period of storing the bit voltage data.

10. The memory device according to claim 9, wherein the second voltage is greater than the predetermined voltage, the predetermined voltage is greater than the first power voltage, and the first power voltage is greater than the first voltage.
